(19) United States
(12) Patent Application Publication
(10) Pub. No.: US 2025/0347991 A1
(43) Pub. Date: Nov. 13, 2025

(54) METHOD FOR STORING ORGANOTIN COMPOUNDS AND ARTICLE

(71) Applicants: Gelest, Inc., Morrisville, PA (US); Mitsubishi Chemical Corporation, Tokyo (JP)

(72) Inventors: Yuta HIOKI, Tokyo (JP); Hiroshi Fukui, Tokyo (JP); Li Yang, Belle Mead, NJ (US)

(21) Appl. No.: 19/193,094

(22) Filed: Apr. 29, 2025

Related U.S. Application Data
(60) Provisional application No. 63/645,960, filed on May 13, 2024.

(51) Int. Cl. G03F 1/66; C07F 7/22; G03F 7/004; G03F 7/16

(52) U.S. Cl. CPC G03F 1/66; C07F 7/2284; C07F 7/2296; G03F 7/0042; G03F 7/167

(57) ABSTRACT

A method for storing organotin compounds and an article that is particularly useful for maintaining the high purity of organotin compounds for semiconductor applications is described. The method for storing an organotin compound involves storing the organotin compound in a container and filling the headspace of the container with an inert gas, in which the container is a multilayer resin container containing, at least a light-shielding layer, a gas barrier layer, and an innermost layer, and the material constituting the innermost layer in contact with the organotin compound includes perfluoroalkoxyalkane, polytetrafluoroethylene, phenol resin, and/or ultra-high molecular weight polyethylene.

### CROSS-REFERENCE TO RELATED APPLICATIONS

This application claims priority to U.S. provisional application No. 63/645,960, filed May 13, 2024, the disclosure of which is herein incorporated by reference in its entirety.

### BACKGROUND OF THE INVENTION

### Technical Field

The present disclosure relates to a method for storing organotin compounds and an article. More specifically, it relates to a method for storing and transporting highly reactive organotin compounds used as raw material compounds (precursors) for forming resist thin films in semiconductor manufacturing processes, and to an article suitable for such storage and transportation.

### Background Art

In recent years, organotin compounds have been used in precision manufacturing processes for information electronic materials and semiconductors. The organotin compounds used in such materials often require ultra-high purity, and there is a strong demand to suppress purity degradation and impurity contamination not only during manufacturing but also during storage, transportation, and use. Therefore, containers for storing and transporting organotin compounds require excellent corrosion resistance.

Conventionally, containers for storing and transporting organotin compounds include perfluoroalkoxyalkane (PFA) containers, polytetrafluoroethylene (PTFE)-lined containers, and other fluororesin containers, as well as corrosion-resistant stainless steel containers.

Patent Literature 1 discloses the use of a container with a polyperfluoroalkoxyethylene coating formed on the inner surface of a metal container to prevent contamination by impurities. Additionally, Patent Document 2 discloses using containers with light-blocking and chemical resistance properties, such as resin containers or stainless steel containers with PTFE liner sheets, for handling organotin compounds.
[Patent Literature 1] Japanese Patent Application Publication No. 2015-534256
[Patent Literature 2] Japanese Patent Application Publication No. 2020-122960 (U.S. Publication No. 2020/239498)

### SUMMARY OF THE INVENTION

### Problems to be Solved by the Invention

However, the coating layer formed by coating the inner surface of a metal container with a fluororesin has lower hardness and inferior scratch resistance compared to a metal, raising concerns that resin scraped off due to damage to the coating layer may mix into the organotin compound as foreign matter. On the other hand, using uncoated metal containers raises concerns about metal elution from the inner surface, particularly during cleaning with acidic aqueous solutions. Especially for highly reactive organotin compounds, there is a risk of reaction with the metal or coating layer of the container surface, making the issues of container corrosion and surface component elution more pronounced.

Additionally, organotin compounds are a type of organometallic compound, and the tin atom can change its valence state through redox reactions. It is also known that organic groups bonded to the tin atom can undergo transmetalation, shifting to the same or different metal species, which raises concerns about metal elution. However, the allowable level of metal impurities is extremely low.

Furthermore, if the organotin compound has hydrolyzable groups, it can easily react with water and decompose, leading to a decrease in purity. Therefore, strict airtightness is required, and corrosion and contamination must be strictly avoided. Liquids, in particular, are more prone to impurity contamination than gases and are more susceptible to elution from objects they come into contact with during transportation, especially when impurities ionize and elute, making separation difficult.

Organotin compounds are also prone to decomposition by heat and light, further complicating the maintenance of their purity.

Recently, there has been an increasing demand for higher quality in ultra-precision electronic components, including semiconductor devices. As a result, the requirements for purity control of organotin compounds have become even more stringent, necessitating further improvements in the technology for storing and transporting organotin compounds.

The properties required of containers may vary depending on the context in which the organotin compound is stored. For example, when the container is connected to a semiconductor manufacturing apparatus and supplies the organotin compound to the apparatus, it is equipped with various accessories and is expensive. In such cases, there is a need for reusable metal containers that can stably maintain the purity of the organotin compound and are environmentally friendly. On the other hand, when transporting bulk quantities from the manufacturing site to the usage site, lightweight and sturdy containers are preferred, and disposable containers may be acceptable.

In view of these circumstances, the present disclosure aims to provide a method for storing organotin compounds and an article that can maintain the high purity of organotin compounds, which are particularly useful for semiconductor applications.

### Means for Solving the Problems

The inventors of the present disclosure conducted extensive research in light of the above circumstances and found that by filling the headspace of a container storing organotin compounds with a highly pure inert gas such as argon, which has low reactivity and is difficult to displace with air, or by using specific resin materials to enhance corrosion resistance, gas barrier properties, airtightness, and light shielding, the high purity of organotin compounds can be maintained. This led to the completion of the present invention.

That is, the present invention includes the following aspects:

[1]

A method for storing an organotin compound, comprising:
providing a multi-layer container having a headspace, storing the organotin compound in the container, and filling the headspace of the container with an inert gas,
wherein the multi-layer container comprises a light-shielding layer, a gas barrier layer, and an innermost layer,
wherein the material constituting the innermost layer comprises at least one resin selected from the group consisting of polytetrafluoroethylene, phenol resin, polyethylene, and polyamide.
   [2]

The method for storing an organotin compound according to [1], wherein the organotin compound has formula (I):

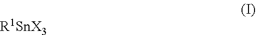

wherein R¹ is a hydrocarbon group with 1 to 20 carbon atoms, which may be substituted with a halogen atom, X is a hydrolyzable group, and R¹ and one X may be bonded to form a cyclic structure.
[3]

The method for storing an organotin compound according to [1] or [2], further comprising connecting a connection pipe to a top surface portion of the container.

[4]

The method for storing an organotin compound according to [1] to [3], wherein the inert gas is argon gas.

[5]

The method for storing an organotin compound according to [4], wherein a purity of the argon gas is 99.999% or higher.

[6]

The method for storing an organotin compound according to [4], wherein an oxygen concentration in the argon gas is 3 ppm or less by volume.

[7]

The method for storing an organotin compound according to [2] to [6], wherein X is a halogen atom, a dialkylamino group, or an alkoxy group which may be substituted with a fluorine atom.

[8]

The method for storing organotin compounds according to [1] to [7], wherein an oxygen permeability converted to 25 μm thickness at 25° C. and 65% RH of the gas barrier layer is 100 cm³/m²·24 h·atm or less.

[9]

The method for storing an organotin compound according to [1] to [8], wherein the gas barrier layer is a resin layer comprising at least one selected from the group consisting of ethylene-vinyl alcohol copolymer, metaxylylenediamine-adipic acid copolycondensate, polyethylene terephthalate, polyamide, vinylidene chloride, and polychlorotrifluoroethylene; a material layer comprising at least one selected from the group consisting of silicon oxide, aluminum oxide, and diamond-like carbon; or a resin film on which silicon oxide, aluminum oxide, and/or diamond-like carbon is vapor-deposited or coated.

[10]

The method for storing an organotin compound according to [1] to [9], wherein the light-shielding layer comprises at least one material selected from the group consisting of polyethylene, polypropylene, polyethylene terephthalate, polyvinyl chloride, polyamide, and ABS resin.

[11]

The method for storing an organotin compound according to [1] to [10], wherein the light-shielding layer contains a coloring agent.

[12]

The method for storing an organotin compound according to [1] to [11], wherein the light-shielding layer is the outermost layer.

[13]

The method for storing an organotin compound according to [11], wherein the coloring agent is red iron oxide or carbon black.

[14]

The method for storing an organotin compound according to [1] to [13], wherein the gas barrier layer is the outermost layer.

[15]

The method for storing an organotin compound according to [1] to [14], wherein the gas barrier layer is positioned between the light-shielding layer and the innermost layer.

[16]

The method for storing an organotin compound according to [1] to [15], wherein the material constituting the innermost layer is high-density polyethylene or ultra-high molecular weight polyethylene.

[17]

The method for storing an organotin compound according to [1] to [16], wherein a storage period is 5 days or longer.

[18]

The method for storing an organotin compound according to [1] to [17], wherein the resin container is molded by extrusion molding using an inflation method, extrusion molding using a T-die, or blow molding.

[19]

An article comprising an organotin compound having formula (I) stored in a multi-layer container, wherein a headspace of the container is filled with an inert gas,
the multi-layer container comprises a light-shielding layer, a gas barrier layer, and an innermost layer,
wherein the innermost layer comprises at least one material selected from the group consisting of polytetrafluoroethylene, phenol resin, polyethylene, and polyamide:

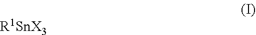

wherein R¹ is a hydrocarbon group with 1 to 20 carbon atoms, which may be substituted with a halogen atom, X is a hydrolyzable group, and R¹ and one X may be bonded to form a cyclic structure.
[20]

The article according to [19], wherein the inert gas comprises argon gas with a purity of 99.9995% or higher.

[21]

The article according to [19] or [20], wherein, in the organotin compound, X is a halogen atom, a dialkylamino group, or an alkoxy group which may be substituted with a fluorine atom.

[22]

A method for producing a coating solution, comprising:
removing the organotin compound from the article according to and mixing it with an organic solvent.
   [23]

A pattern forming method comprising:
removing the organotin compound from the article according to and coating it onto a substrate, or coating a coating liquid obtained by mixing the removed organotin compound with an organic solvent onto a substrate to form a thin film;
irradiating the thin film with active energy rays to obtain a thin film with a latent image; and
developing the thin film with the latent image to obtain a substrate having a patterned layer.
   [24]

A pattern forming method comprising: removing the organotin compound from the article according to and supplying it to a CVD apparatus;
reacting the organotin compound with water in the CVD apparatus while depositing it onto a substrate to form a thin film on the substrate;
irradiating the thin film with active energy rays to obtain a thin film with a latent image; and
developing the thin film with the latent image to obtain a substrate having a patterned layer.
   [25]

A method for storing an organotin compound, comprising providing a container having a headspace, storing the organotin compound in the container, and filling the headspace of the container with argon gas having a purity of 99.999% or higher.

[26]

The method for storing an organotin compound according to [25], wherein the purity of the argon gas is 99.9995% or higher.

[27]

The method for storing an organotin compound according to [25] or [26], wherein the organotin compound has formula (I):

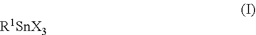

wherein R¹ is a hydrocarbon group with 1 to 20 carbon atoms, which may be substituted with a halogen atom, X is a hydrolyzable group, and R¹ and one X may be bonded to form a cyclic structure.
[28]

The method for storing an organotin compound according to [25] to [27], wherein the container is a glass container provided with a light-shielding layer on an outer side.

### Effects of the Invention

According to the present disclosure, it is possible to provide a method for storing organotin compounds and an article that can maintain the high purity of organotin compounds, which is particularly useful for semiconductor applications.

### BRIEF DESCRIPTION OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 A schematic cross-sectional view of a resin container used in a storage method according to an embodiment of the present disclosure.

FIG. 2 A schematic cross-sectional view showing the layer structure of a resin container used in a storage method according to an embodiment of the present disclosure.

FIG. 3 A schematic cross-sectional view showing the layer structure of a resin container used in a storage method according to an embodiment of the present disclosure.

FIG. 4 A schematic cross-sectional view showing the layer structure of a resin container used in a storage method according to an embodiment of the present disclosure.

FIG. 5 A schematic cross-sectional view of a resin container used in a storage method according to an embodiment of the present disclosure.

FIG. 6 A schematic diagram of a container used for storage in Example 1 and Comparative Example 1.

FIG. 7 A schematic diagram showing the state of the container in FIG. 6 when opened to the atmosphere.

FIG. 8 A graph showing the results of Comparative Examples 4-6 with respect to the change over time of the purity of Compound (1).

### DETAILED DESCRIPTION OF THE INVENTION

### Mode for Carrying Out the Invention

### First Embodiment

Below, a method for storing organotin compounds and an article according to a first embodiment will be described. As used herein, the term “storage” includes not only simply keeping the organotin compound in a container, but also forms of holding the organotin compound in a container for a certain period or longer, such as when placing it in a container for transportation.

### [Method for Storing Organotin Compounds]

The storage method of organotin compounds according to the first embodiment includes providing a multi-layer container having a headspace, storing an organotin compound in the container, and filling the headspace of the container with an inert gas. The multi-layer container includes at least a light-shielding layer, a gas barrier layer, and an innermost layer.

The material constituting the innermost layer that contacts the organotin compound includes at least one resin selected from the group consisting of polytetrafluoroethylene (PTFE), phenolic resin (PF), polyethylene (PE), and polyamide (PA). This innermost layer has chemical resistance to organotin compounds and is not corroded by organotin compounds.

In addition, the light-shielding layer prevents photodegradation of the organotin compound by blocking visible light, ultraviolet light, etc. The light-shielding layer uses a resin having light-blocking properties or a resin containing light-blocking materials.

Furthermore, the gas barrier layer prevents deterioration of the organotin compound by blocking gases such as oxygen and water vapor that are reactive with the organotin compound. For the gas barrier layer, materials other than resins, such as inorganic materials with gas barrier properties, may be used in addition to resins with gas barrier properties.

In other words, a resin container as described herein refers to a container having a light-shielding layer, a gas barrier layer, and an innermost layer, of which at least the light-shielding layer and the innermost layer contain resin.

### (Organotin Compounds)

In the present disclosure, “organotin compounds” refers to compounds containing at least a tin atom, a carbon atom, a hydrogen atom, and a C—H bond in the molecule.

Organotin compounds often react easily with water and air and are flammable at room temperature. Additionally, organotin compounds are prone to transmetalation, a reaction in which the central metal is replaced by another metal.

Organotin compounds with an Sn—C bond in the molecule have low Sn—C bond energy and may decompose easily under heat or light.

Organotin compounds with hydrolyzable groups in the molecule are prone to hydrolysis and may convert into compounds with Sn—O—Sn bonds, such as stannoxanes.

Organotin compounds with both hydrocarbon groups and hydrolyzable groups, i.e., compounds with both Sn—C bonds and hydrolyzable groups, may undergo disproportionation reactions represented by the following scheme, where R represents a hydrocarbon group and X represents a hydrolyzable group.

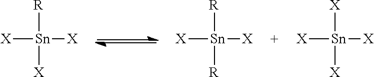

The storage method of this embodiment is particularly useful for maintaining the high purity of organotin compounds with Sn—C bonds and/or hydrolyzable groups.

Organotin compounds used as precursors for extreme ultraviolet (EUV) resists, in particular, require high purity, such as 99% or higher. Therefore, it is essential to minimize impurities such as metals, halogen atoms, and decomposition products of organotin compounds, and to adopt a storage method that can suppress the aforementioned reactions and decomposition.

In particular, resin containers have the advantage of being easily formed into multiple layers, making it easy to configure them to meet all requirements for gas barrier properties, light-blocking properties, and chemical resistance. Moreover, they are less likely to break compared to glass, they do not introduce Na contamination, and compared to metals, they are lightweight and do not require surface treatment on the inside.

Organotin compounds used as precursors for EUV resists or organotin compound that are their synthetic intermediates are preferably represented by the following formula:

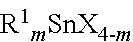

In the above formula, R¹ is a hydrocarbon group having 1 to 20 carbon atoms which may be substituted with halogen atoms, X is a hydrolyzable group, and m is an integer of 0 to 2. When m=1, R¹ and one of X may be bonded to form a cyclic structure. When m=2, the two R¹ groups may be the same hydrocarbon group or different hydrocarbon groups.

Among these, compounds where m=1, that is, compounds represented by the following formula (I), are more preferable:

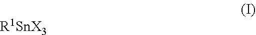

Hereinafter, organotin compounds represented by formula (I) are also referred to as compound (I).

The hydrocarbon group R¹ may be linear, branched, or cyclic. It may be saturated or unsaturated and may be aliphatic or aromatic. The number of carbon atoms in R¹ is preferably 1 to 10, more preferably 3 to 8. Halogen atoms that may substitute R¹ include chlorine, fluorine, bromine, and iodine.

Examples of R¹ include alkyl groups such as methyl, ethyl, propyl, isopropyl, butyl, isobutyl, sec-butyl, t-butyl, cyclopentyl, and cyclohexyl; alkenyl groups such as vinyl, allyl, 2-butenyl, 3-butenyl, and 1-cyclopentenyl; alkynyl groups such as ethynyl and 2-propynyl; aryl groups such as phenyl and tolyl; and aralkyl groups such as benzyl, phenethyl, and α-methylbenzyl.

Hydrocarbon groups R¹ where the carbon atom bonded to the tin atom is secondary or tertiary are preferred. This is because radicals generated during EUV irradiation are relatively stable, leading to lower C—Sn bond dissociation energy and higher EUV irradiation efficiency when used as EUV resist precursors. From a productivity standpoint, R¹ is more preferably an isopropyl or t-butyl group.

Examples of X include halogen atoms, amino groups, alkoxy groups (—OR′), alkynide groups (R′C≡C—), azido groups (N3-), dialkylamino groups (—NR′₂, —NR′R″), N-alkylacylamino groups (—N(R′)C(O)R′, —N(R′)C(O)R″, —N(R″)C(O)R′), acyloxy groups (—OCOR′), and acylamino groups (—N(H)C(O)R′). Here, R′ and R″ are independently hydrocarbon groups with 1 to 10 carbon atoms, which may be substituted with halogen atoms, and may be different from each other.

In formula (I), multiple X groups may be the same or different.

Examples of R′ and R″ hydrocarbon groups include, for example, alkyl groups such as a methyl group, ethyl group, propyl group, isopropyl group, butyl group, isobutyl group, sec-butyl group, t-butyl group, cyclopentyl group, cyclohexyl group, 1-methyl-1-cyclopentyl group, t-amyl group (2-methyl-2-butyl group), 1,1,1-trifluoro-2-methyl-2-propyl group (trifluoro-t-butyl group); aryl groups such as a phenyl group, tolyl group; and aralkyl groups such as a benzyl group, phenethyl group, and α-methylbenzyl group.

Preferred X groups include dialkylamino groups, alkoxy groups which may be substituted with fluorine atoms, alkylcarbonylamino groups, halogen atoms, and carbonyloxy groups. More preferred are halogen atoms, dialkylamino groups, and alkoxy groups which may be substituted with fluorine atoms. Particularly preferred are dialkylamino groups (—NR′₂) and alkoxy groups (—OR′). Here, R′ is a hydrocarbon group having 1 to 10 carbon atoms. The two R′ groups in the dialkylamino group may be linked to form a ring.

When X is a dialkylamino group, dimethylamino, diethylamino, and pyrrolidinyl groups (where the two R′ groups form a 5-membered ring) are more preferred. When X is an alkoxy group, from the viewpoint of stability, alkoxy groups where R′ is a tertiary alkyl group are more preferred, with t-butyl group, t-amyl group, and 1,1,1-trifluoro-2-methyl-2-propyl group (trifluoro-t-butyl group) being even more preferred.

The organotin compound (I) has one Sn—C bond that serves as a radical source during EUV irradiation and can form a network of Sn—O—Sn bonds at three-points when hydrolyzed, making it suitable for resist film formation.

Organotin compounds (I) where R¹ and one X are bonded to form a cyclic structure when m=1 include, for example, compounds represented by the following formulas (II) and (III).

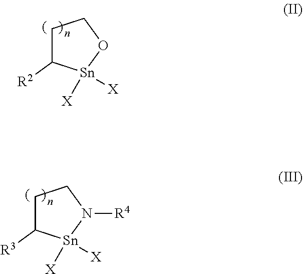

In formula (II), X is a hydrolyzable group, and R² is a hydrogen atom or a hydrocarbon group with 1 to 20 carbon atoms, which may be substituted with a halogen atom.

In formula (III), X is a hydrolyzable group, R³ is a hydrogen atom or a hydrocarbon group with 1 to 20 carbon atoms, which may be substituted with a halogen atom, and R⁴ is an alkyl group with 1 to 10 carbon atoms.

In formulas (II) and (III), X is the same as in formula (I), and the preferred embodiments are also the same. The hydrocarbon group with 1 to 20 carbon atoms, which may be substituted with a halogen atom. R² and R³ may be the same groups as R¹, and the preferred embodiments are also the same.

In formulas (II) and (III), X is preferably an alkoxy group (—OR′) or a dialkylamino group (—NR′₂).

R² is preferably a hydrogen atom or an alkyl group with 1 to 4 carbon atoms.

R³ is preferably a hydrogen atom or an alkyl group with 1 to 4 carbon atoms.

R⁴ is preferably an alkyl group with 1 to 4 carbon atoms.

Organotin compounds may be stored as a mixture of two or more types, but to prevent unintended reactions, it is preferable to store them as a single type.

The purity of the organotin compound stored in the container is preferably 95.0% or higher, more preferably 99.0% or higher, and particularly preferably 99.5% or higher for use as a high-purity resist material. Regarding impurities, if compounds with Sn—O bonds (hereinafter sometimes referred to as Sn-O impurities) that have a different structure from the target organotin compound are generated as impurities, they may form cluster structures and become insoluble substances in the target organotin compound, so their content must be suppressed. When used as a resist material in semiconductor manufacturing processes, Sn—O impurities may cause clogging of equipment, contamination, and increased roughness of patterns, which is particularly problematic. Especially during transportation, storage, and transfer, the increase of Sn—O impurities in the storage container makes management and purification before use as a resist material extremely difficult, so their increase must be suppressed. Specifically, the content of compounds with Sn—O bonds (Sn—O impurities) that have a different structure from the target organotin compound should be suppressed to 5.0% or less, 3.0% or less, 1.0% or less, or even 0.5% or less for each compound. It is also preferable that these impurities do not easily increase during storage (including the leak state described later).

The purity (%) of the target organotin compound as described herein refers to the molar percentage of tin atoms in the ¹¹⁹Sn-NMR, which is the ratio of the tin atoms in the target organotin compound to the total number of tin atoms in all compounds (including unidentified compounds). Practically, it is calculated by dividing the integral value of the target organotin compound's peak by the sum of the integral values of all observed peaks in the ¹¹⁹Sn-NMR.

For analysis using ¹¹⁹Sn-NMR, to improve sensitivity, the target organotin compound is analyzed without dilution, using a large number of accumulations (1,000 or more, preferably 10,000 or more), sufficient relaxation time (1 second or more), and inverse-gate decoupling conditions. As a result, the detection limit for tin compounds may reach 0.01 mol %. Additionally, if the sensitivity of the measurement peaks is still insufficient, high-sensitivity NMR ((e.g., using an Ultra-low temperature probe (for example, CryoProbe (registered trademark), etc.) may be used to further enhance detection sensitivity.

Organotin compounds may also be diluted and stored in solvents. Exemplary solvents include ether solvents such as diethyl ether, dimethoxyethane, and tetrahydrofuran; alcohol solvents such as isopropanol, t-butanol, t-amyl alcohol, 4-methyl-2-pentanol, and hydrocarbon solvents such as hexane, heptane, and decane.

### (Container)

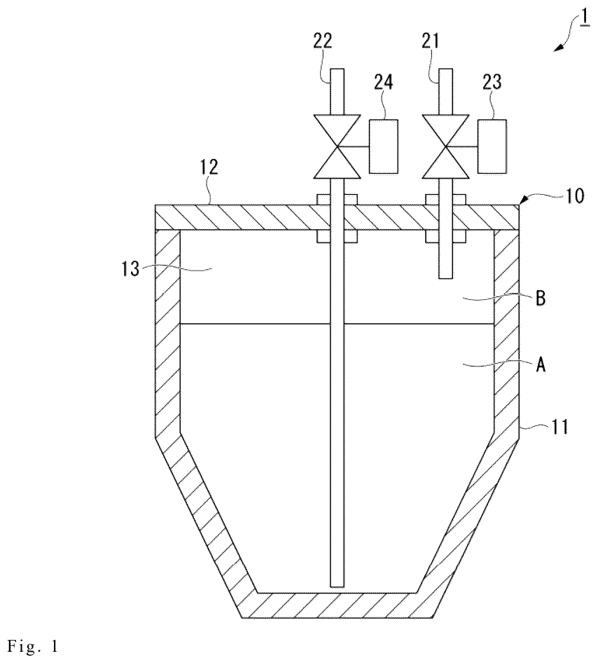

An example of a resin container used in the storage method of the embodiment is shown in FIG. 1.

The resin container 10 shown in FIG. 1 comprises a container body 11 with an open top and a lid 12 that seals the opening of the container body 11.

By storing the organotin compound A in the resin container 10 and filling the headspace 13 above the organotin compound A with an inert gas B, the decomposition of the organotin compound A stored in the resin container 10 may be suppressed.

The shape of the container body 11 is not particularly limited, but as shown in FIG. 1, the inner surface shape may be such that the bottom of the cylinder is an inverted truncated cone. When the container body 11 has such an inner surface shape, the amount of organotin compound A remaining in the resin container 10 during discharge may be minimized. The shape of the container body 11 may be modified as needed depending on the purpose, such as a chamfered rectangular parallelepiped shape, which is typical for poly tanks, or a cylindrical shape with a bottom for storage and transportation purposes.

The dimensions of the container body 11 may be set as appropriate.

The form of the lid 12 is not particularly limited as long as it may seal the opening of the container body 11 and hermetically seal the organotin compound A and inert gas B inside the resin container 10.

It is preferable to place a gasket between the resin container 10 and the lid 12 to enhance airtightness.

In this example, the lid 12, which forms the top part of the resin container 10, is connected to a first connection pipe 21 and a second connection pipe 22.

The first connection pipe 21 is a connection pipe for introducing the organotin compound into the resin container 10. The first connection pipe 21 is equipped with a valve 23.

The lower end of the first connection pipe 21 inside the container 10 is positioned above the organotin compound A when the organotin compound A is stored in the resin container 10. This allows the organotin compound A to be smoothly introduced into the resin container 10 through the first connection pipe 21.

The second connection pipe 22 is a connection pipe for discharging the organotin compound A stored in the resin container 10 and transferring it to another container or device. The second connection pipe 22 is equipped with a valve 24.

The lower end of the second connection pipe 22 inside the resin container 10 is positioned as close to the bottom of the container body 11 as possible to minimize the residual amount of organotin compound A during discharge.

The resin container 10 may be sealed by closing the valve 23 installed on the first connection pipe 21 and the valve 24 installed on the second connection pipe 22.

When introducing the inert gas B into the resin container 10, either the first connection pipe 21 or the second connection pipe 22 may be used. Alternatively, a separate connection pipe for introducing the inert gas may be connected to the lid 12, apart from the first and second connection pipes. When connecting a separate inert gas introduction pipe, it is preferable to install a valve on that pipe to ensure that the resin container 10 may be sealed.

### (Multilayer Structure of the Resin Container)

The resin container 10 has a multilayer structure comprising at least a light-shielding layer 10C, a gas barrier layer 10B, and an innermost layer 10A.

The innermost layer, because it comes in contact with the organotin compound stored in the resin container 10, needs to be a layer with chemical resistance (corrosion resistance, elution resistance) to the organotin compound. It is also preferable that the container has high cleanability (does not elute in cleaning solutions such as acids, has abrasion resistance, is easy to remove dirt from, and does not readily retain water or solvents used for cleaning).

The gas barrier layer is a layer for preventing the entry of oxygen and water vapor into the resin container, thereby suppressing the decomposition of the organotin compound that would result from reaction with these substances.

The light-shielding layer is a layer for blocking light from entering the resin container, thereby suppressing the decomposition of the organotin compound caused by light.

The arrangement of the gas barrier layer in the resin container 10 is not particularly limited as long as it is located outside the innermost layer and inside the light-shielding layer.

The light-shielding layer may be the outermost layer, but an outer layer to maintain the container's strength may also be added outside the light-shielding layer.

To maintain the container's strength or for manufacturing convenience, an intermediate layer may be added between the innermost layer and the gas barrier layer or between the gas barrier layer and the light-shielding layer.

An adhesive layer may be placed between each layer of the resin container 10, or each layer may have adhesive properties.

The placement of the gas barrier layer in the resin container 10 is not particularly limited as long as it is outside the innermost layer. That is, it may have a configuration with a light-shielding layer, gas barrier layer, and innermost layer from the outside, or a configuration with a gas barrier layer, light-shielding layer, and innermost layer from the outside.

The light-shielding layer or gas barrier layer may be provided as the outermost layer, but an outer layer may be further provided outside the light-shielding layer or gas barrier layer, for example, to maintain the strength of the container.

To maintain the strength of the container or for convenience in container manufacturing, an intermediate layer may be provided between the innermost layer and the gas barrier layer, between the innermost layer and the light-shielding layer, or between the gas barrier layer and the light-shielding layer.

An adhesive layer may be provided between each layer of the resin container 10, or each layer may have adhesive properties.

In the resin container 10, among the layers described above, a single layer having both light-shielding and gas barrier functions may be provided instead of separate light-shielding and gas barrier layers. For example, by adding a coloring agent to a resin with gas barrier properties, both light-shielding and gas barrier functions may be achieved.

In the resin container 10, it is preferable to provide a light-shielding layer that also maintains the container's strength, or to provide an outer layer that maintains the container's strength outside the light-shielding layer. When the gas barrier layer is positioned between the light-shielding layer and the innermost layer, the gas barrier performance tends to be maintained at a high level for a long period, which is preferable as it improves the stability of the contents.

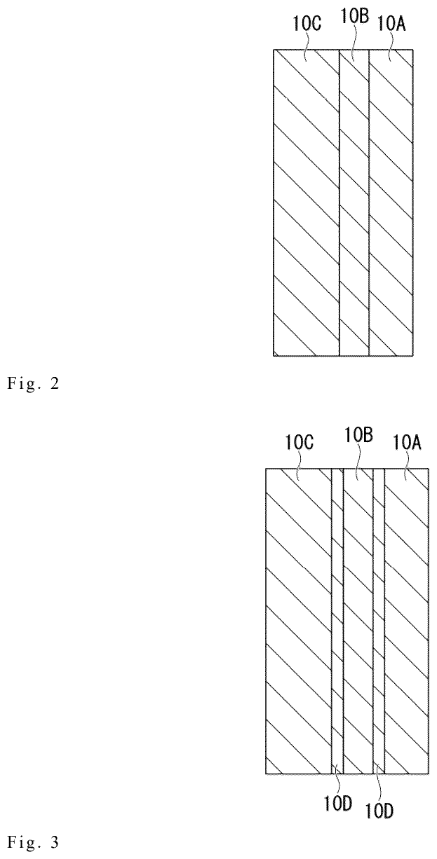

For the multilayer structure of the resin container 10, for example, as shown in FIG. 2, a structure having a light-shielding layer 10C, a gas barrier layer 10B, and an innermost layer 10A in order from the outside is appropriate. Also, in FIG. 2, the positions of the light-shielding layer and the gas barrier layer may be switched to form a structure with a gas barrier layer 10B, a light-shielding layer 10C, and an innermost layer 10A in order from the outside.

As shown in FIG. 3, the structure may have a light-shielding layer 10C, an adhesive layer 10D, a gas barrier layer 10B, an adhesive layer 10D, and an innermost layer 10A in order from the outside. Also, in FIG. 3, the positions of the light-shielding layer and the gas barrier layer may be switched to form a structure with a gas barrier layer 10B, an adhesive layer 10D, a light-shielding layer 10C, an adhesive layer 10D, and an innermost layer 10A in order from the outside.

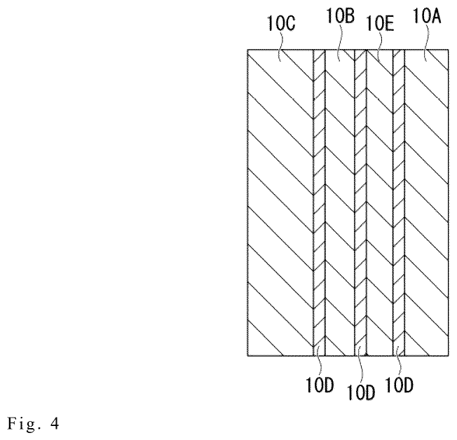

As shown in FIG. 4, the structure may have a light-shielding layer 10C, an adhesive layer 10D, a gas barrier layer 10B, an adhesive layer 10D, an intermediate layer 10E, an adhesive layer 10D, and an innermost layer 10A in order from the outside.

Among these examples, when the light-shielding layer 10C is the outermost layer, it is preferable that it also serves the function of maintaining the strength of the container in addition to blocking light.

The material constituting the innermost layer 10A contains at least one selected from the group consisting of polytetrafluoroethylene (PTFE), phenolic resin (PF), polyamide (PA), and polyethylene (PE). These resins may be used alone or in combination of two or more.

These materials have extremely low reactivity with organotin compounds. Therefore, the innermost layer 10A containing at least one of these materials has excellent chemical resistance.

Among polyethylenes, high-density polyethylene (HDPE) or ultra-high molecular weight polyethylene (UHMWPE) is preferable because it can minimize the amount of resin particles.

The molecular weight of ultra-high molecular weight polyethylene is typically 1 million to 7 million. The density of high-density polyethylene is typically 0.93 to 0.97 (g/cm³), preferably 0.935 to 0.96 (g/cm³). If the density is too low, rigidity decreases, and if the density is too high, impact resistance deteriorates. The melt flow index (MFR) is typically 30 to 0.01 (g/10 min), preferably 2 to 0.02 (g/10 min).

Additionally, for the resin constituting the innermost layer, it is preferable that the content of polymers with a weight average molecular weight of 1×10³ or less, as measured by gel permeation chromatography (GPC) in the resin composition, is less than 5% by weight. This may suppress the mixing of particles into the contents (high-purity chemicals, etc.).

As a material included in the innermost layer 10A, PTFE, a fluorine-based resin, is preferable from the viewpoint of chemical resistance and container cleanability. From the viewpoint of balance of necessary physical properties, ultra-high molecular weight polyethylene is more preferable. This is because ultra-high molecular weight polyethylene has excellent abrasion resistance, strength, chemical resistance, container cleanability, impact resistance, moldability, and adhesion to other layers, and has a low specific gravity of 0.92 to 0.94, making it easy to reduce the weight of the resin container 10. It is also inexpensive and easy to dispose of as a general-purpose resin, making it preferable for use in disposable containers or containers with limited use. Also, high-density polyethylene is preferable from the viewpoint of moldability and versatility.

The thickness of the innermost layer 10A is preferably 1 mm or more, more preferably 2 mm or more, and preferably 5 mm or less, more preferably 3 mm or less. The preferred range of thickness for the innermost layer 10A may be combined arbitrarily, for example, 1 to 5 mm is preferable, and 2 to 3 mm is more preferable.

The gas barrier layer 10B is not particularly limited as long as it has gas barrier properties, and materials with an oxygen permeability of 100 cm³/m²·24 h·atm or less when converted to a thickness of 25 μm at 25° C., 65% RH are preferable. An oxygen permeability of 20 cm³/m²·24 h. atm or less is more preferable, and 5 cm³/m²·24 h. atm or less is particularly preferable. Specifically, exemplary gas barrier layers include resin layers containing at least one selected from the group consisting of ethylene-vinyl alcohol copolymer (EVOH), metaxylylenediamine-adipic acid copolycondensate, polyethylene terephthalate (PET), vinylidene chloride (PVDC), polychlorotrifluoroethylene (PCTFE), and polyamide (PA); a material layer containing at least one selected from the group consisting of silicon oxide (silica), aluminum oxide (alumina), and diamond-like carbon (DLC); and resin films on which at least one of materials are vapor-deposited or coated.

Examples of metaxylylenediamine-adipic acid copolycondensate include “Nylon MXD6” manufactured by Mitsubishi Gas Chemical Company, Inc. Also, as an adhesive resin with gas barrier properties, “MX-Nylon” (a mixture of polyepoxy resin and polyamine resin) manufactured by Mitsubishi Gas Chemical Company, Inc. may be used.

Examples of ethylene-vinyl alcohol copolymer include “EVAL” manufactured by Kuraray Co., Ltd. and “Soarnol™” manufactured by Mitsubishi Chemical Corporation.

Examples of silica vapor-deposition films include “TechBarrier™” manufactured by Mitsubishi Chemical Corporation.

As substrate films for vapor-deposition films such as diamond-like carbon vapor-deposition films, silicon oxide vapor-deposition films, and aluminum oxide vapor-deposition films, resin films such as the resins exemplified for the above resin layer, and hydrocarbon resins such as polyethylene and polypropylene may be used.

The thickness of the gas barrier layer 10B may be appropriately set depending on the material.

The thickness of the gas barrier layer 10B is preferably 0.01 mm or more, more preferably 0.1 mm or more, and even more preferably 1 mm or more. It is also preferably 5 mm or less, more preferably 3 mm or less, and even more preferably 1 mm or less. The preferred range of thickness for the gas barrier layer 10B may be combined arbitrarily, for example, 0.01 to 5 mm is preferable, and 0.01 to 1 mm is more preferable.

As the light-shielding layer 10C, for example, as a layer that maintains the strength of the container, a layer in which a coloring agent is added to a resin layer, or a layer in which a coloring agent is painted or printed on the surface of a resin layer are appropriate. These light-shielding layers are preferably used as the outermost layer for visibility.

As the light-shielding layer 10C, a layer in which a coloring agent is added to a resin layer is preferable from the viewpoint of productivity and maintenance of the light-shielding layer.

The resin constituting the resin layer of the light-shielding layer 10C is not particularly limited, and examples include polyethylene (PE), polypropylene (PP), polyethylene terephthalate (PET), polycarbonate (PC), polyvinyl chloride (PVC), acrylonitrile butadiene styrene copolymer (ABS), polymethyl methacrylate (PMMA), perfluoroalkoxyalkane (PFA), polyamide (PA), etc. These resins may be used alone or in combination of two or more.

As the resin constituting the light-shielding layer 10C, it is preferable to include at least one selected from the group consisting of polyethylene, polypropylene, polyethylene terephthalate, polyvinyl chloride, polyamide, and ABS resin. Also, from the viewpoint of mechanical strength and chemical resistance, polyethylene and polypropylene are more preferable, and polyethylene (PE) and polypropylene are even more preferable. An advantage of these resins is that weather resistance may be covered by adding coloring agents as described later. Regarding the light-shielding degree, for example, in the resin container 10, it is preferable that the minimum absorbance of all layers of the container at wavelengths of 400 nm or less, as measured by a spectrophotometer, is 2.0 or more, and the absorption coefficient at a wavelength of 400 nm, obtained by dividing the absorbance of all layers of the container by the thickness of all layers, is 1.5 mm⁻¹ or more, and the absorption coefficient at a wavelength of 600 nm is 1.5 mm⁻¹ or less.

As the coloring agent, pigments that may be mixed into the resin may be used, but darker colors are preferable from the perspective of blocking light, with red iron oxide and carbon black being more preferable.

When mixing a coloring agent into the resin layer, the amount of coloring agent is preferably 1 part by mass or more, more preferably 5 parts by mass or more, and preferably 30 parts by mass or less, more preferably 15 parts by mass or less, per 100 parts by mass of the resin in the resin layer. The preferred lower and upper limits for the amount of coloring agent may be combined arbitrarily, for example, 1 to 30 parts by mass is preferable, and 5 to 15 parts by mass is more preferable.

When a coloring agent is mixed into the resin layer, the thickness of the light-shielding layer 10C is preferably 1 mm or more, more preferably 2 mm or more, and preferably 5 mm or less, more preferably 3 mm or less. The preferred lower and upper limits for the thickness of the light-shielding layer 10C may be combined arbitrarily, for example, 1 to 5 mm is preferable, and 2 to 3 mm is more preferable.

Methods for coating or printing the coloring agent on the surface of the resin layer include, for example, urethane coating, lacquer coating, acrylic coating, plastic plating, and printing.

For the light-shielding layer 10C formed by coating or printing on the resin layer, the thickness of the resin layer is preferably 1 mm or more, more preferably 2 mm or more, and preferably 5 mm or less, more preferably 3 mm or less. The preferred lower and upper limits for the thickness of the resin layer may be combined arbitrarily, for example, 1 to 5 mm is preferable, and 2 to 3 mm is more preferable.

The thickness of the layer formed by coating or printing is preferably 0.06 to 0.1 mm.

As the outer layer for maintaining the strength of the container, for example, the resin layer described for the light-shielding layer may be adopted.

The thickness of the outer layer is preferably 1 mm or more, more preferably 2 mm or more, and preferably 5 mm or less, more preferably 3 mm or less. The preferred lower and upper limits for the thickness of the outer layer may be combined arbitrarily, for example, 1 to 5 mm is preferable, and 2 to 3 mm is more preferable.

Examples of materials constituting the adhesive layer 10D include acrylic adhesives, silicone adhesives, urethane adhesives, rubber adhesives, and epoxy adhesives. These may be used alone or in combination of two or more.

The thickness of the adhesive layer 10D is preferably 0.03 mm or more, more preferably 0.05 mm or more, and preferably 0.2 mm or less, more preferably 0.15 mm or less. The preferred lower and upper limits for the thickness of the adhesive layer 10D may be combined arbitrarily, for example, 0.03 to 0.2 mm is preferable, and 0.05 to 0.15 mm is more preferable.

The intermediate layer 10E may be, for example, a layer for maintaining the strength of the container. As the intermediate layer 10E, for example, the resin layer described for the light-shielding layer may be adopted.

The thickness of the intermediate layer 10E is preferably 1 mm or more, more preferably 2 mm or more, and preferably 5 mm or less, more preferably 3 mm or less. The preferred lower and upper limits for the thickness of the intermediate layer 10E may be combined arbitrarily, for example, 1 to 5 mm is preferable, and 2 to 3 mm is more preferable.

The thickness of the resin container 10 may be set as appropriate depending on the capacity. For example, for a 5 L container, preferably the thickness may be about 2 to 20 mm, and more preferably about 2 to 10 mm.

The method for manufacturing the multilayer resin container 10 is not particularly limited, and the container may be molded by preferred molding methods including inflation extrusion molding, T-die extrusion molding, and blow molding. Blow molding is particularly preferable because it allows for easy molding of multilayer resin containers.

### (Inert Gas)

The inert gas B may be any gas that is non-flammable, non-combustible, and inert to organotin compounds.

Examples of the inert gas B include argon gas, neon gas, helium gas, carbon dioxide gas, and nitrogen gas. From the perspective of versatility, argon gas and nitrogen gas are preferable. Argon gas is most preferable due to its lower reactivity at high temperatures, its heavier weight compared to air, which makes it easier to replace air in the container, and its resistance to being replaced by air in the event of minor leaks during long-term storage or use. Additionally, argon gas suppresses static electricity during the transportation, storage, and use of organotin compounds and has unique solubility properties that contribute to the safety and product quality of each process, making it preferable.

The purity of the inert gas B is preferably 99.999% or higher, more preferably 99.9995% or higher, and particularly preferably 99.9999% or higher to ensure stable storage of the organotin compound. Furthermore, when high-purity argon gas is used in the process of using the organotin compound (semiconductor manufacturing process), stricter management is required to avoid introducing different gases as impurities into the equipment, making a purity of 99.9999% or higher particularly preferable.

The concentration of impurities in the inert gas B (oxygen concentration, hydrogen concentration, carbon monoxide concentration, carbon dioxide concentration, THC (total hydrocarbon) concentration is preferably 5 ppm or less by volume for each, more preferably 3 ppm or less, 1 ppm or less, 0.5 ppm or less, or 0.1 ppm or less. The moisture content is preferably a dew point of −75° C. or lower, more preferably −80° C. or lower. Additionally, when the inert gas B is argon, the nitrogen concentration is preferably 1 ppm or less, more preferably 0.5 ppm or less.

### (Leak State Evaluation)

As described above, storage is premised on being sealed with inert gas. However, due to the nature of storage containers, there is a possibility that atmospheric gases may mix in during storage or that the organotin compound may be slightly exposed to the atmosphere during handling (filling, transportation, transfer, use), sometimes referred to as a leak state. It is preferable to maintain high purity even in such leak states. Specifically, the evaluation method for such storage conditions may involve creating conditions in which the container is exposed to the atmosphere through a fine hole (e.g., 1 mm) to simulate a leak state as an accelerated test. The change in purity or the amount of insoluble matter generated after storage periods such as 8 hours or 72 hours may be compared for evaluation.

### (Sealing Method)

The method for sealing the organotin compound and inert gas into the resin container is not particularly limited as long as it can suppress the decomposition of the organotin compound. A preferred method involves introducing inert gas into the resin container, replacing all the air in the container with inert gas, and then introducing the organotin compound into the container. During the replacement of inert gas, it is preferable to perform drying and removal of residual gases through replacement operations (reduced pressure or inert gas flow) and, if necessary, repeat the reduced pressure or inert gas flow operations. During these operations, it is preferable to ensure that the entire container (including piping, if any), especially the headspace portion that comes into contact with the solution during storage, is sufficiently replaced with inert gas.

Additionally, methods for introducing the organotin compound into the resin container include filling under an inert gas atmosphere using equipment or pressure-feeding into a container that has been replaced with inert gas. Filling under an inert gas atmosphere is preferably performed in a glove box, and more preferably in a glove box under a high-purity argon gas atmosphere. Pressure-feeding into a container under an inert gas atmosphere may be done by pressure-feeding the organotin compound into the container using the same inert gas. These methods are selected based on the size of the container, the material of the container, the shape of the valve arrangement, etc.

### (Storage Temperature)

Since organotin compounds may decompose at high temperatures, the storage temperature is preferably 30° C. or lower, more preferably −10 to 25° C. For long-term storage over several months, it is preferable to store at as low a temperature as possible (−10 to 10° C.).

### (Storage Period)

With respect to the storage period, there are no particular restrictions. In the short term, storage may be for 1 day or more, 3 days or more, or 5 days or more. Also, when using the above resin container and sealing with inert gas, by controlling the temperature, storage for more than 1 week, more than 1 month, furthermore more than 3 months, or more than 6 months is possible. On the other hand, considering the potential deterioration of the resin container and product delivery, the storage period is normally 3 years or less, and preferably 1 year or less.

### [Article]

The article according to the first embodiment has an organotin compound stored in a resin container, with inert gas sealed in the headspace of the container. The container is a multilayer container, such as a multilayer resin container including at least a light-shielding layer, a gas barrier layer, and an innermost layer. The material constituting the innermost layer, which contacts the organotin compound, contains at least one selected from the group consisting of polytetrafluoroethylene (PTFE), phenolic resin (PF), polyethylene (PE), and polyamide (PA).

An example of an article according to the first embodiment is shown in FIG. 1, where the organotin compound A is stored in the resin container 10, and the headspace 13 of the resin container 10 is filled with inert gas B.

The organotin compound, resin container 10, connection piping, and inert gas are as described above.

### Second Embodiment

Below, the method for storing organotin compounds and the article according to the second embodiment will be described.

### [Method for Storing Organotin Compounds]

The method for storing organotin compounds according to the second embodiment comprises providing a container having a headspace, storing the organotin compound in the container, and filling the headspace of the container with argon gas having a purity of 99.999% or higher.

Argon gas is heavier than air, making it easier to replace air in the container. Once replaced, it is less likely to be replaced by air if the container is opened (leaked). Additionally, argon gas has low reactivity with organotin compounds even at high temperatures. By filling the headspace of the container with argon gas, oxygen and water vapor in the container are replaced with argon gas, which has low reactivity with the organotin compound, thereby suppressing decomposition and reactions during high-temperature operations.

### (Organotin Compound)

The “organotin compound” is as described in the first embodiment, and the preferred embodiments are the same.

### (Container)

For the container used in the second embodiment, in addition to the resin container used in the first embodiment, a glass container may also be employed.

Since glass containers possess gas barrier properties and chemical resistance against organotin compounds, a separate light-shielding layer may be provided on an outer side. For example, the glass container may be covered with aluminum foil or another light-blocking material. Alternatively, instead of adding a light-shielding layer, colored glass, such as amber glass, may be used.

While glass is inexpensive and versatile, it is also fragile. Therefore, the glass container (inner container) may be enclosed within an outer container made of resin or metal, and a cushioning material may be placed between the inner and outer containers as needed. In this case, the resin or metal may also be given light-shielding properties.

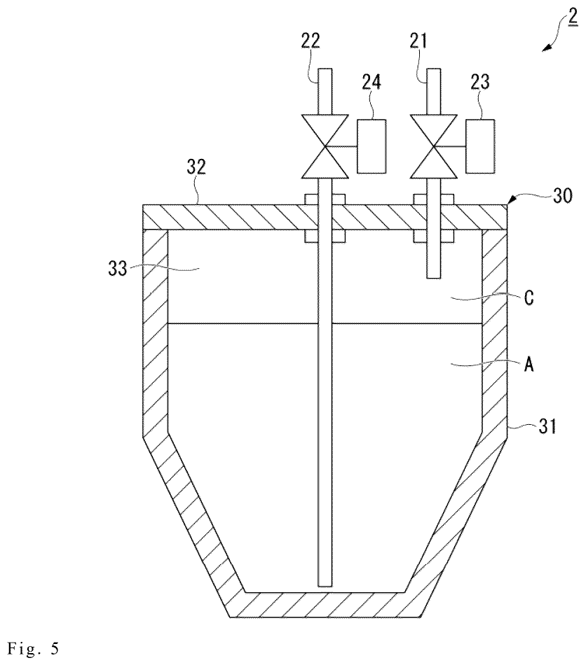

An example of a resin container used in the storage method of the organotin compound according to the first and second embodiments is shown in FIG. 5.

The container 30 shown in FIG. 5 comprises a container body 31 with an open top and a lid 32 that seals the opening of the container body 31.

The organotin compound A is stored inside the container 30, and the headspace 33 above the stored organotin compound A is filled with argon gas C having a purity of 99.999% or higher. This suppresses the decomposition of the organotin compound A stored in the container 30.

### (Light-Shielding Layer)

As the light-shielding layer 10C in the second embodiment, a metal foil such as aluminum foil or a metal-deposited film such as aluminum-deposited film may be used. Particularly when the container body is made of glass, since multilayer molding is not feasible, wrapping the entire glass container with metal foil or a metal-deposited film is a simple solution. In this case, the outer layer serves as the light-shielding layer, while the inner layer functions as both a gas barrier layer and an innermost layer (chemical-resistant layer), resulting in a two-layer container structure.

The thickness of the metal foil constituting the light-shielding layer 10C is preferably 0.003 mm or more, more preferably 0.006 mm or more, and preferably 0.5 mm or less, more preferably 0.02 mm or less.

The preferred lower and upper limits of the metal foil thickness my be freely combined. For example, 0.003-0.5 mm is preferable, and 0.006-0.02 mm is more preferable.

The thickness of the metal-deposited layer in the metal-deposited film constituting the light-shielding layer 10C is preferably 0.003 mm or more, more preferably 0.006 mm or more, and preferably 0.5 mm or less, more preferably 0.02 mm or less.

The preferred lower and upper limits of the metal-deposited layer thickness may be freely combined. For example, 0.003-0.5 mm is preferable, and 0.006-0.02 mm is more preferable.

The thickness of the film in the metal-deposited film is preferably 1 mm or more, more preferably 2 mm or more, and preferably 5 mm or less, more preferably 3 mm or less.

The preferred lower and upper limits of the film thickness may be freely combined. For example, 1-5 mm is preferable, and 2-3 mm is more preferable.

The descriptions of the container body 11 and lid 12 in the first embodiment apply directly to the container body 31 and lid 32.

In the lid 32 forming the top portion of this example container 30, similar to the resin container 10 illustrated in the first embodiment, a first connection pipe 21 equipped with a valve 23 and a second connection pipe 22 equipped with a valve 24 are connected. The first connection pipe 21 and second connection pipe 22 are the same as in the first embodiment.

When introducing argon gas into the container 30, either the first connection pipe 21 or the second connection pipe 22 may be used. Alternatively, a separate connection pipe for introducing argon gas may be connected to the lid 32, apart from the first and second connection pipes. When connecting a separate argon gas introduction pipe, it is preferable to install a valve on that pipe to ensure that the container 30 may be sealed.

The container 30 is preferably the multilayer resin container described above, but is not limited thereto. For example, glass or metal containers may also be used. Glass has gas barrier properties and is non-reactive with organotin compounds, while metal has gas barrier properties and light-shielding properties. Therefore, when using glass, the glass should be used in combination with a light-shielding material. When using metal, a material that is non-reactive with tin compounds should be used as the innermost layer, or surface treatment should be applied to reduce the reactivity of the metal.

### (Argon Gas)

The purity of the argon gas C is preferably 99.999% or higher, more preferably 99.9995% or higher, and particularly preferably 99.9999% or higher.

The oxygen concentration in the argon gas C is preferably 5 ppm or less by volume, more preferably 3 ppm or less.

### (Sealing Method)

The method for sealing the organotin compound and argon gas into the container 30 may be performed in the same manner as described for the resin container 10.

### [Article]

An article according to the second embodiment comprises an organotin compound stored in a container, with the headspace of the container filled with argon gas having a purity of 99.999% or higher.

An example of an article according to the second embodiment is shown in FIG. 5, where the organotin compound A is stored in the container 30, and the headspace 33 of the container 30 is filled with argon gas C having a purity of 99.999% or higher.

The organotin compound, container, and argon gas are as described above.

### [Pattern Formation Method]

An organotin compound represented by the formula (I) is stored in a container, with an inert gas enclosed in the headspace of the container. The container has a multilayer structure comprising at least a light-shielding layer, a gas barrier layer, and an innermost layer, where the material forming the innermost layer includes at least one selected from polytetrafluoroethylene, phenolic resin, polyethylene, and polyamide. The organotin compound is removed from the container and used to form a thin film derived from the tin compound on a substrate.

Methods for forming the thin film on the substrate include: applying the tin compound directly, or applying a coating solution prepared by mixing the tin compound removed from the container with an organic solvent.

Organic solvents used in the coating solution may include ether solvents such as diethyl ether, dimethoxyethane, and tetrahydrofurane; alcohol solvents such as isopropanol, t-butanol, t-amyl alcohol, 4-methyl-2-pentanol; and hydrocarbon solvents such as hexane, heptane, and decane.

Alternatively, the organotin compound may be removed from the container, supplied to a CVD apparatus, and deposited on the substrate while reacting with water in the CVD apparatus to form the thin film. The thickness of the thin film formed on the substrate is preferably 10 to 100 nm, more preferably 10 to 50 nm. The substrate is preferably a silicon substrate commonly used in semiconductor chip manufacturing.

The thin film may be irradiated with active energy rays to obtain a thin film with a latent image. Examples of active energy rays include electron beams, ultraviolet rays, deep ultraviolet rays, and extreme ultraviolet rays. Preferred active energy rays are extreme ultraviolet rays with a wavelength of 6 to 15 nm, particularly 6.5 to 13.5 nm. By irradiating the thin film on the substrate with active energy rays, a latent image-bearing thin film containing a desired pattern may be obtained.

The latent image-bearing thin film may be developed to obtain a substrate with a patterned layer. Development methods include: developing the latent image-bearing thin film with a developing solution, or developing the latent image-bearing thin film with a gas. Through this development process, the desired pattern is formed on the substrate.

Furthermore, the method for storing the organotin compound and the article of the present invention are not limited to the aforementioned embodiments. Within the scope not departing from the spirit of the present invention, it is possible to appropriately replace components in the described embodiments with well-known components, and the aforementioned modifications may be suitably combined as needed.

### EXAMPLES

Next, the present invention will be described in detail using examples. However, the present invention is not limited to the following examples.

### <Manufacturing of Resin Containers>

### Manufacturing Example 1 (Prophetic)

A resin container with a multilayer structure comprising a light-shielding layer outer layer, an adhesive layer, a gas barrier layer, an adhesive layer, an intermediate layer, an adhesive layer, and an innermost layer, as shown in FIG. 4, is manufactured. The light-shielding layer is a material with carbon black (Mitsubishi Carbon Black MA600) mixed into PE, the gas barrier layer is EVOH, the intermediate layer is PE, the innermost layer is PTFE, and the adhesive layer is an adhesive.

The container body and lid are formed by co-extrusion molding of five layers: PE mixed with carbon black, adhesive, EVOH, adhesive, and PE. The inner surface of these parts is then lined with PTFE by adhesive lining to manufacture the resin container. The container body has the inner surface shape shown in FIG. 1, where the bottom of the cylinder is an inverted truncated cone. A flat round gasket made of PFA is placed between the lid and the container body. The lid (top part) is connected to a first connection pipe for introducing the organotin compound, a second connection pipe for discharging the organotin compound, and a connection pipe for introducing and discharging inert gas.

### Manufacturing Example 2 (Prophetic)

A resin container is manufactured in the same manner as Manufacturing Example 1, except that the PE used to form the light-shielding layer is not mixed with carbon black, and the outer layer is changed to a non-light-shielding layer. The connection pipes are then connected.

### <Manufacturing of Organotin Compounds>

### Manufacturing Example 3

Isopropyltris(dimethylamino) tin, used as the organotin compound for the storage test, was prepared using the following manufacturing method.

A 200 L glass reactor and a stirring device (stirring blade: twin star, diameter: 350 mm, width: 110 mm) were used. The reactor was replaced with nitrogen three times under reduced pressure. Special grade hexane (36.6 kg, moisture content: 30 ppm) and n-butyllithium (41.0 kg, 96.8 mol, 15% hexane solution, 3.09 eq) were added to the reactor and stirred at 150 rpm. Dimethylamine (8.69 kg, 193.6 mol, 6.18 eq) was then added dropwise while maintaining the temperature between −5° C. and 10° C.

The resulting dimethyl lithium amide slurry was stirred at 23-27° C. for 5 hours. The temperature of the slurry was adjusted to 0° C., and isopropyltrichlorotin (8.40 kg, 31.3 mol, 1.00 eq, purity: over 99.9 mol %) in hexane solution (4.20 kg) was added dropwise over 3 hours while maintaining the internal temperature between 0° C. and 10° C. After the addition, the temperature was raised to 20-25° C., and the mixture was stirred at this temperature for 16 hours. The reaction solution was filtered using a pressure filter to remove the white solid (LiCl), yielding a clear filtrate. The white solid was further washed with dehydrated hexane (7.3 kg×3), and the filtrates were combined.

The resulting reaction solution was concentrated under reduced pressure to obtain 9.3 kg of a crude tin compound containing isopropyltris(dimethylamino) tin. The crude tin compound was distilled using a glass distillation apparatus wrapped with light-shielding cloth under conditions of an internal temperature of 70-80° C. and a reduced pressure of 0.3 kPa, yielding 6.1 kg of isopropyltris(dimethylamino) tin (organotin compound (1)) as the distillate.

The purity of the obtained organotin compound (1) was measured by ¹¹⁹Sn-NMR and found to be 99.31%. The detailed composition is shown in Table 2.

### <Storage Test of Organotin Compounds>>

### Example 1

### (1) Storage in an Argon-Filled Container

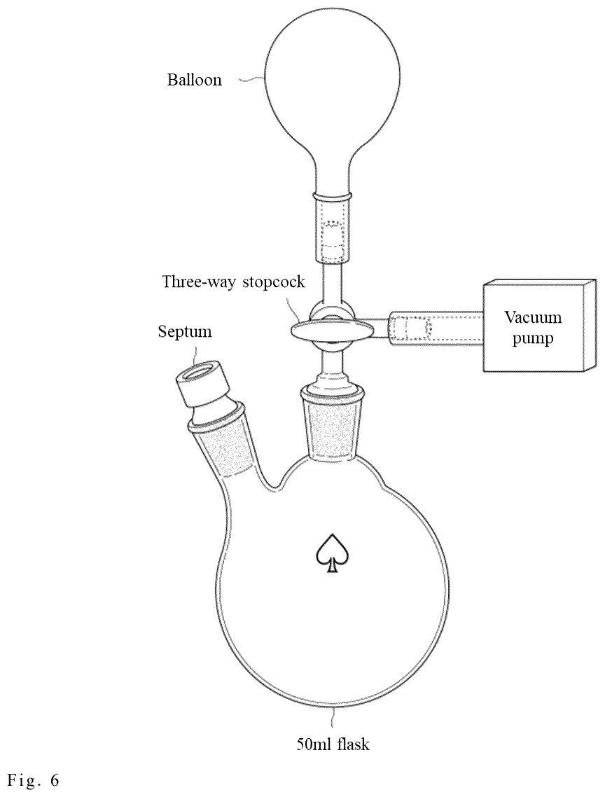

As shown in FIG. 6, a rubber stopper (Merck Precision Seal® septum rubber) was attached to one outlet of a two-necked 50 mL glass flask, and a three-way cock (flow path diameter: 1 mm) was connected to the other outlet. One line of the three-way cock was connected to a balloon filled with Grade 1 argon gas (G1Ar, Taiyo Nippon Sanso Corporation) as shown in Table 1, and the other line was connected to a vacuum pump. By operating the three-way cock, the vacuum pump (reduced pressure: 10 Pa), the flask, and the argon balloon were sequentially connected, and the flask was purged with argon gas. This operation was repeated three times, and the three-way cock was set to connect the argon balloon and the flask. The entire container was then wrapped with aluminum foil as a light-shielding layer to block light from the glass surface. Using a syringe purged with the same argon gas, 5 mL of the organotin compound (1) obtained in Manufacturing Example 3 was pressure-fed into the flask through the septum rubber inlet, and the organotin compound (1) was stored in the container with argon filling the headspace. In other words, the organotin compound (1) was stored in a container with a light-shielding layer of aluminum foil, a gas barrier layer of glass, and an innermost layer of glass, filled with high-purity argon.

### (2) Leak Test

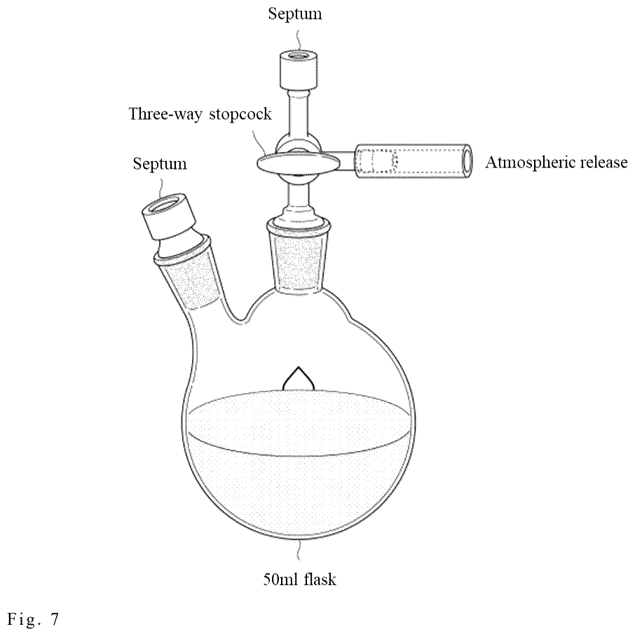

As shown in FIG. 7, the vacuum pump was removed from the three-way cock line, and one outlet of the three-way cock was opened to the atmosphere. By operating the three-way cock to connect the atmospheric opening and the inside of the flask, the flask was exposed to the atmosphere through a 1 mm diameter flow path. The container was stored at 15-25° C. while maintaining the light-shielding conditions. Samples of the organotin compound (1) were taken after 8 hours and 72 hours of atmospheric exposure and analyzed by ¹¹⁹Sn-NMR. The results are shown in Table 2.

### Comparative Example 1

The storage of the organotin compound (1) under nitrogen-filled conditions was performed in the same manner as in Example 1, except that Grade 1 nitrogen gas (G1N2, Taiyo Nippon Sanso Corporation) was used instead of Grade 1 argon gas. Samples of the organotin compound (1) were taken after 8 hours and 72 hours of atmospheric exposure and analyzed by ¹¹⁹Sn-NMR. The results are shown in Table 2.

TABLE 1

| | Type | Ar | N₂ |
|---|---|---|---|
| | Grade | G1 | G1 |
| Inert Gas | Purity | >99.9999 vol. % | >99.9995 vol. % |
| Impurities | N₂ | <0.3 vol. ppm | — |

| O₂ | <0.1 vol. ppm | <0.1 | vol. ppm |
|---|---|---|---|
| H₂ | <0.1 vol. ppm | — | |
| CO | <0.1 vol. ppm | <0.1 | vol. ppm |
| CO₂ | <0.1 vol. ppm | <0.1 | vol. ppm |
| THC | <0.1 vol. ppm | <0.05 | vol. ppm |
| NOₓ | — | <0.01 | vol. ppm |
| SO₂ | — | <0.01 | vol. ppm |

| | | |
|---|---|---|
| H₂O | below −80° C. | below −80° C. |

Table 2 shows the analysis results of the organotin compound (1) after 8 hours of atmospheric exposure in Example 1 and Comparative Example 1 as Example 1-1 and Comparative Example 1-1, respectively, and after 72 hours of atmospheric exposure as Example 1-2 and Comparative Example 1-2, respectively.

In Table 2, the compounds corresponding to the chemical shifts in the ¹¹⁹Sn-NMR are as follows. The peaks at −104 ppm, −134 ppm, and −136 ppm are presumed to have Sn—O structures, suggesting that they were formed by reactions with water or oxygen.
18 ppm: iPr₂Sn(NMe₂)₂
64 ppm: iPrSn(NMe₂)₃
82 ppm: iPrSn(NMeCH₂NMe₂)(NMe₂)₂
104 ppm: iPrSn(OiPr)(NMe₂)₂ (compound with Sn—O structure formed by reaction with water or oxygen)
134 ppm: Presumed to be a compound with an Sn—O structure formed by reaction with water or oxygen
136 ppm: Presumed to be a compound with an Sn—O structure formed by reaction with water or oxygen

In the above compounds, iPr represents an isopropyl group, and Me represents a methyl group.

The evaluation of the amount of insoluble matter generated in Table 2 was performed by visually inspecting the appearance of the contents and rated on the following five-point scale. Note that “cloudiness” refers to turbidity equivalent to 50 degrees or higher on the kaolin standard based on JIS K0101.
1: No cloudiness in the solution. No insoluble matter adhering to or precipitating on the container walls.
2: No cloudiness in the solution. Insoluble matter adhering to or precipitating on part of the container walls.
3: Cloudiness in the solution. No insoluble matter adhering to or precipitating on the container walls.
4: Cloudiness in the solution. Insoluble matter adhering to or precipitating on part of the container walls.

TABLE 2

| | | | | | | | | | | Number of |
|---|---|---|---|---|---|---|---|---|---|---|
| | Inert | Storage | Chemical Shift (ppm) | | | | | | | Decomposition |
| | Gas | Time | −18 | −64 | −82 | −104 | −134 | −136 | Total | Products |
| Initial | — | — | 0.20% | 99.31% | 0.49% | — | — | — | 100.00% | 1 |
| Comparative | N₂ | 8 h | 0.20% | 98.69% | 1.02% | 0.09% | — | — | 100.00% | 1 |
| Example 1-1 | | | | | | | | | | |
| Example 1-1 | Ar | 8 h | 0.20% | 99.19% | 0.61% | 0.00% | — | — | 100.00% | 1 |
| Comparative | N₂ | 72 h | 0.18% | 90.79% | 7.56% | 0.25% | 0.50% | 0.72% | 100.00% | 4 |
| Example 1-2 | | | | | | | | | | |
| Example 1-2 | Ar | 72 h | 0.18% | 91.65% | 7.00% | 0.20% | 0.49% | 0.48% | 100.00% | 2 |

From comparing the purity of the organotin compound (1) in Examples 1-1 and 1-2 and Comparative Examples 1-1 and 1-2, it may be seen that Examples 1-1 and 1-2, which used argon filling, maintained higher purity even under leak conditions. In other words, when storing the organotin compound (1) in a container with a light-shielding layer, a gas barrier layer, and an innermost layer, filling with argon suppresses the generation of impurities and insoluble matter that may occur due to reactions with oxygen or water, even if minor leaks to the atmosphere occur during storage or handling, thereby maintaining the stability of the organotin compound (1).

### Example 2 (Prophetic)

After filling the multilayer resin container manufactured in Manufacturing Example 1 with argon gas with a purity of 99.9999% or higher and an oxygen concentration of 0.1 ppm or less by volume, the organotin compound (1) obtained in Manufacturing Example 3 is introduced into the resin container in a glove box under an argon gas atmosphere, filling about half of the resin container with the organotin compound (1). In this state, the headspace of the resin container is filled with argon gas.

The container containing the organotin compound (1) is exposed to light using a halogen lamp and maintained at 25° C. for 72 hours.

In Example 2, almost no decomposition of the organotin compound (1) is observed.

### Example 3 (Prophetic)

The organotin compound (1) is stored in the multilayer resin container in the same manner as in Example 2, except that the storage temperature is set to 100° C. without halogen lamp irradiation.

In Example 3, almost no decomposition of the organotin compound (1) is observed.

### Comparative Example 2 (Prophetic)

The organotin compound (1) is stored in a container in the same manner as in Example 2, except that the container is changed to a glass container.

In Comparative Example 2, due to the poor light-shielding properties of the glass container, most of the organotin compound (1) decomposes under light, forming iPrSn(NMe₂)(NMeCH₂NMe₂) and Sn(NMe₂)₂. Here, iPr represents an isopropyl group, and Me represents a methyl group.

### Example 4 (Prophetic)

The organotin compound (1) is stored in a container in the same manner as in Example 3, except that the container is changed to a PTFE container.

In Example 4, due to the slightly inferior light-shielding and gas barrier properties of the container, a small portion of the organotin compound (1) undergoes hydrolysis, and a small portion decomposes under light.

### Comparative Example 3 (Prophetic)

The organotin compound (1) is stored in the resin container in the same manner as in Example 2, except that argon gas is not filled into the resin container.

A portion of the organotin compound decomposes due to moisture and oxygen in the air inside the resin container.

### Example 5 (Prophetic)

The organotin compound (1) is stored in a container in the same manner as in Example 3, except that the container is changed to a PFA container colored with red iron oxide.

In Example 5, a small portion of the organotin compound (1) decomposes due to oxygen and water vapor. Additionally, slight yellowing, presumably due to a reaction between PFA and the organotin compound, is observed.

### Example 6 (Prophetic)

The organotin compound (1) is stored in a container in the same manner as in Example 2, except that the container is changed to the resin container from Manufacturing Example 2.

In Example 6, a small portion of the organotin compound (1) decomposes under light.

### Example 7 (Prophetic)

The organotin compound (1) is stored in a container in the same manner as in Example 3, except that the container is changed to a stainless steel container made of SUS316.

In Example 7, slight discoloration, presumably due to corrosion of the stainless steel container by the organotin compound (1), is observed.

### Reference Example 1 (Prophetic)

The organotin compound (1) is stored in the resin container in the same manner as in Example 3, except that nitrogen gas is used instead of argon gas to fill the headspace of the resin container.

In Reference Example 1, almost no decomposition of the organotin compound (1) is observed.

However, nitrogen molecules can exhibit reactivity in the presence of metals at high temperatures, and nitrogen gas is more reactive than argon gas. Therefore, when transferring the organotin compound from the container to the next apparatus for high-temperature processing, the inert gas used for storage in the container is also carried into the next apparatus, making argon gas more advantageous. Additionally, since nitrogen gas is lighter than air, while argon gas is heavier, argon gas is less likely to leave residual air in the container, which is also advantageous.

### Comparative Example 4

An organotin compound (1) was stored in a resin container under the same conditions as in Example 2, except that a PFA container was used, the entire container was wrapped with aluminum foil for light shielding, and nitrogen was used as the inert gas.

### Comparative Example 5

An organotin compound (1) was stored in a resin container under the same conditions as in Example 2, except that a brown 100 mL high-density polyethylene container (Aicello CLEANBARRIER® CB) was used, the entire container was wrapped with aluminum foil for light shielding, and nitrogen was used as the inert gas.

### Comparative Example 6

An organotin compound (1) was stored in a resin container under the same conditions as in Example 2, except that a white 100 mL high-density polyethylene container (Aicello CLEANBARRIER® CB) was used, the entire container was wrapped with aluminum foil for light shielding, and nitrogen was used as the inert gas.

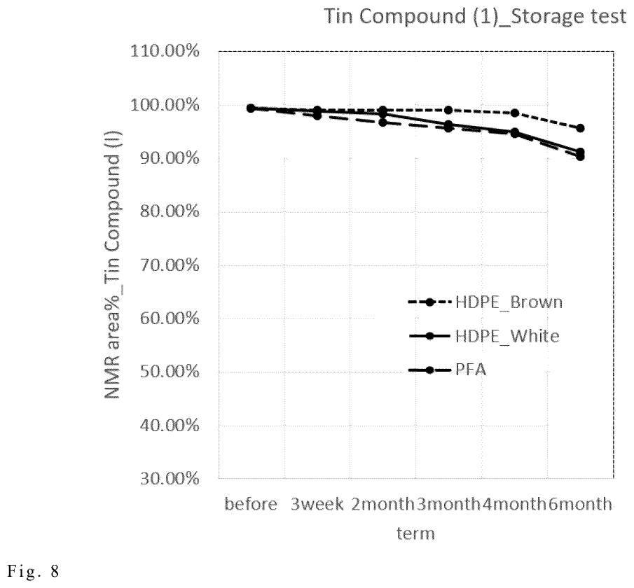

The results of Comparative Examples 4-6 are shown in FIG. 8. In all cases, the organotin compound (1) gradually decomposed. This is thought to be primarily due to insufficient gas barrier properties of the resin containers.

### [Example 8] (Prophetic)

A container is used consisting of a two-layer structure with an inner layer of non-colored polyethylene (density 0.94) and an outer layer of brown-colored polyethylene (density 0.94), with the entire outer surface coated with silica (silicon dioxide). Here, the non-colored polyethylene serves as the chemical-resistant layer, the brown-colored polyethylene as the light-shielding layer, and the silica coating as the gas barrier layer. The organotin compound (1) is stored in the resin container under the same conditions as in Example 2, except that nitrogen is used as the inert gas. Almost no decomposition of the organotin compound is observed over 6 months.

### [Example 9] (Prophetic)

Using the same container as in Example 8, the organotin compound (1) is stored in the resin container under the same conditions as in Example 2, except that Grade 1 argon (99.9999% purity or higher) is used as the inert gas. Almost no decomposition of the organotin compound is observed over 6 months.

### [Example 10] (Prophetic)

A container is used where the entire outer surface of the two-layer resin container from Example 8 is equipped with a silica-deposited PET resin (“Techbarrier™” manufactured by Mitsubishi Chemical Corporation). The organotin compound (1) is stored in the resin container under the same conditions as in Example 8. Almost no decomposition of the organotin compound is observed over 6 months.

### [Example 11] (Prophetic)

The organotin compound is stored in a resin container under the same conditions as in Example 9, except that a three-layer resin container is used with the following structure from outer to inner layers: brown-colored polyethylene (density 0.94: light-shielding layer), ethylene-vinyl alcohol copolymer (gas barrier layer), and non-colored polyethylene (density 0.94: innermost layer). Almost no decomposition of the organotin compound is observed over 6 months.

As described above, using a multilayer resin container with chemical resistance, light-shielding properties, and gas barrier properties, and filling the headspace of the resin container with inert gas, suppresses the decomposition of the organotin compound.

### INDUSTRIAL APPLICABILITY

The storage method of the present invention allows for the long-term storage and transportation of organotin compounds while maintaining high purity without degrading their quality. Therefore, this storage method enables the stable handling of high-quality organotin compounds, making it particularly useful for consistently providing high-quality semiconductor products.

### EXPLANATION OF SYMBOLS

1, 2: Article
10: Resin container
10A: Innermost layer
10B: Gas barrier layer
10C: Light-shielding layer
10D: Adhesive layer
10E: Intermediate layer
11: Container body
12: Lid
13: Headspace
21: First connection pipe
22: Second connection pipe

We claim:

1. A method for storing an organotin compound, comprising:
providing a multi-layer container having a headspace, storing the organotin compound in the container, and filling the headspace of the container with an inert gas,
wherein the multi-layer container comprises a light-shielding layer, a gas barrier layer, and an innermost layer,
wherein the material constituting the innermost layer comprises at least one resin selected from the group consisting of polytetrafluoroethylene, phenol resin, polyethylene, and polyamide.

2. The method for storing an organotin compound according to claim 1, wherein the organotin compound has formula (I): 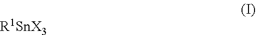
wherein R¹ is a hydrocarbon group with 1 to 20 carbon atoms, which may be substituted with a halogen atom, X is a hydrolyzable group, and R¹ and one X may be bonded to form a cyclic structure.

3. The method for storing an organotin compound according to claim 1, further comprising connecting a connection pipe to a top surface portion of the container.

4. The method for storing an organotin compound according to claim 1, wherein the inert gas is argon gas.

5. The method for storing an organotin compound according to claim 4, wherein a purity of the argon gas is 99.999% or higher.

6. The method for storing an organotin compound according to claim 4, wherein an oxygen concentration in the argon gas is 3 ppm or less by volume.

7. The method for storing an organotin compound according to claim 2, wherein X is a halogen atom, a dialkylamino group, or an alkoxy group which may be substituted with a fluorine atom.

8. The method for storing organotin compounds according to claim 1, wherein an oxygen permeability converted to 25 μm thickness at 25° C. and 65% RH of the gas barrier layer 100 cm³/m²·24 h·atm or less.

9. The method for storing an organotin compound according to claim 1, wherein the gas barrier layer is a resin layer comprising at least one selected from the group consisting of ethylene-vinyl alcohol copolymer, metaxylylenediamine-adipic acid copolycondensate, polyethylene terephthalate, polyamide, vinylidene chloride, and polychlorotrifluoroethylene; a material layer comprising at least one selected from the group consisting of silicon oxide, aluminum oxide, and diamond-like carbon; or a resin film on which silicon oxide, aluminum oxide, and/or diamond-like carbon is vapor-deposited or coated.

10. The method for storing an organotin compound according to claim 1, wherein the light-shielding layer comprises at least one material selected from the group consisting of polyethylene, polypropylene, polyethylene terephthalate, polyvinyl chloride, polyamide, and ABS resin.

11. The method for storing an organotin compound according to claim 1, wherein the light-shielding layer contains a coloring agent.

12. The method for storing an organotin compound according to claim 1, wherein the light-shielding layer is the outermost layer.

13. The method for storing an organotin compound according to claim 11, wherein the coloring agent is red iron oxide or carbon black.

14. The method for storing an organotin compound according to claim 1, wherein the gas barrier layer is the outermost layer.

15. The method for storing an organotin compound according to claim 1, wherein the gas barrier layer is positioned between the light-shielding layer and the innermost layer.

16. The method for storing an organotin compound according to claim 1, wherein the material constituting the innermost layer is high-density polyethylene or ultra-high molecular weight polyethylene.

17. The method for storing an organotin compound according to claim 1, wherein a storage period is 5 days or longer.

18. The method for storing an organotin compound according to claim 1, wherein the resin container is molded by extrusion molding using an inflation method, extrusion molding using a T-die, or blow molding.

19. An article comprising an organotin compound having formula (I) stored in a multi-layer container, wherein a headspace of the container is filled with an inert gas,
the multi-layer container comprises a light-shielding layer, a gas barrier layer, and an innermost layer,
wherein the innermost layer comprises at least one material selected from the group consisting of polytetrafluoroethylene, phenol resin, polyethylene, and polyamide: 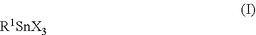
wherein R¹ is a hydrocarbon group with 1 to 20 carbon atoms, which may be substituted with a halogen atom, X is a hydrolyzable group, and R¹ and one X may be bonded to form a cyclic structure.

20. The article according to claim 19, wherein the inert gas comprises argon gas with a purity of 99.9995% or higher.

21. The article according to claim 19, wherein, in the organotin compound, X is a halogen atom, a dialkylamino group, or an alkoxy group which may be substituted with a fluorine atom.

22. A method for producing a coating solution, comprising:
removing the organotin compound from the article according to claim 19 and mixing it with an organic solvent.

23. A pattern forming method comprising:
removing the organotin compound from the article according to claim 19 and coating it onto a substrate, or coating a coating liquid obtained by mixing the removed organotin compound with an organic solvent onto a substrate to form a thin film;
irradiating the thin film with active energy rays to obtain a thin film with a latent image; and
developing the thin film with the latent image to obtain a substrate having a patterned layer.

24. A pattern forming method comprising: removing the organotin compound from the article according to claim 19 and supplying it to a CVD apparatus;
reacting the organotin compound with water in the CVD apparatus while depositing it onto a substrate to form a thin film on the substrate;
irradiating the thin film with active energy rays to obtain a thin film with a latent image; and
developing the thin film with the latent image to obtain a substrate having a patterned layer.

25. A method for storing an organotin compound, comprising providing a container having a headspace, storing the organotin compound in the container, and filling the headspace of the container with argon gas having a purity of 99.999% or higher.

26. The method for storing an organotin compound according to claim 25, wherein the purity of the argon gas is 99.9995% or higher.

27. The method for storing an organotin compound according to claim 25, wherein the organotin compound has formula (I): 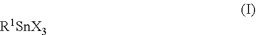
wherein R¹ is a hydrocarbon group with 1 to 20 carbon atoms, which may be substituted with a halogen atom, X is a hydrolyzable group, and R¹ and one X may be bonded to form a cyclic structure.

28. The method for storing an organotin compound according to claim 25, wherein the container is a glass container provided with a light-shielding layer on an outer side.
